(19) United States
(12) Patent Application Publication
(10) Pub. No.: US 2012/0013344 A1
(43) Pub. Date: Jan. 19, 2012

(54) DEVICE FOR DIAGNOSING MEASUREMENT OBJECTS USING A MEASUREMENT VOLTAGE

(75) Inventors: Rudolf Blank, Sulz (AT); Stefan Baldauf, Rankweil (AT)

(73) Assignee: B2 ELECTRONIC GMBH, Klaus (AT)

(21) Appl. No.: 13/244,251

(22) Filed: Sep. 23, 2011

Related U.S. Application Data
(63) Continuation of application No. PCT/EP2010/001931, filed on Mar. 26, 2010.

(30) Foreign Application Priority Data
Apr. 1, 2009 (DE) 10 2009 015 280.6

(51) Int. Cl. G01R 31/02

(52) U.S. Cl. 324/537

(57) ABSTRACT

A device for diagnosing measurement objects using a measurement voltage comprises a housing, in which at least one electric measurement circuit is arranged for carrying out the diagnosis. To this end, the device is designed for the simultaneous diagnosis of a plurality of measurement objects using the same measurement voltage and comprises at least two separate connecting elements for connecting one measurement object each to the measurement voltage. The measurement circuit in turn comprises at least two current detection units and a voltage detection unit, by means of which the current flowing through each measurement object and the measurement voltages present at all measurement objects can be measured at the same time.

### CROSS REFERENCE TO RELATED APPLICATIONS

This is a continuation of PCT/EP2010/001931 filed on Mar. 26, 2010, which claims priority to DE 10 2009 015 280.6 filed on Apr. 1, 2009, the contents of each of which are incorporated herein by reference.

### FIELD OF THE INVENTION

The present invention relates to a device for diagnosing measurement objects using a measurement voltage, comprising a housing, in which there is disposed at least one electrical measurement circuit for carrying out the diagnosis.

### BACKGROUND

A device of this type is known, for example, from WO 2007/045004 A1. The measurement objects to be tested with such a device are in particular (high-voltage) cables or other electrical or electronic components, such as capacitors, coils, etc., which can be subjected to a technical diagnosis by applying a measurement voltage and evaluating the resulting current flow generated in the measurement object.

In the prior art, and also within the scope of the present invention, the diagnosis of a cable brings to mind in particular the (nondestructive) determination of what is known as the loss factor, which permits an estimate of the quality or of the remaining expected useful life of the cable. The measurement voltage used for this purpose is preferably a sinusoidal AC voltage, with which the loss factor can be calculated in conventional manner by evaluating the resulting current generated in the cable, or in other words by evaluating the amplitude and phase thereof compared with the amplitude and phase of the measurement voltage, which is also detected by the device. The use of a DC voltage or other voltage pulses with a pre-defined profile of voltage amplitude, in conjunction with evaluation of the response of the measurement object to an existing current flow, may also be considered for standard diagnostic purposes.

The measurement voltage for this purpose is preferably made available, as described in WO 2007/045004 A1, by a separate (high) voltage generator, which is connected via a suitable interface, especially via a coaxial cable led into the housing of the device, to the electrical measurement circuit of the diagnostic or test device. In principle, however, integration of the (high) voltage source in the device is also conceivable.

The device described in WO 2007/045004 A1 is provided with a connection adapter, which receives the measurement voltage and to which the measurement object to be tested can be connected directly. Furthermore, the measurement circuit of the device comprises a current-detection unit connected to the connection adapter as well as a voltage-detection unit, whose output signals are relayed to an evaluation unit. This evaluation unit is designed to store and condition the data acquired for diagnostic purposes, in order to transmit them to an external data-processing unit and or to evaluate the incoming signals directly, for example in the sense of determining the loss factor of a cable being tested as the measurement object. The result of this measurement or diagnosis may then be displayed if necessary via a suitable (measured-value) display unit of the device.

### SUMMARY

Against this background it is the object of the present invention to improve a measurement or diagnostic device of the type explained in the foregoing and described in detail in WO 2007/045004 A1 to the effect that the greatest possible time savings and improved accuracy can be achieved in a diagnosis of several measurement objects to be tested. In particular, the individual conductors of a multi-core cable can be imagined as the plurality of measurement objects.

The foregoing object is achieved with a device that is characterized not only by the features already mentioned hereinabove but also by the fact that it is designed for simultaneous diagnosis of several measurement objects with the same measurement voltage. This inventive device is provided with at least two separate connection elements, each for connecting one measurement object to the measurement voltage, wherein the measurement circuit of the device comprises at least two current-detection units and (at least) one voltage-detection unit, by means of which the current flowing through each measurement object as well as the measurement voltage applied equally to all measurement objects can be measured simultaneously.

Compared with the already known prior art, the present invention achieves numerous advantages. Firstly, because it is no longer necessary to connect several measurement objects to be exposed to the same measurement voltage sequentially to the device and to subject each separately to a diagnosis, considerable time savings are possible. Furthermore, in view of the circumstance that all measurement objects being tested simultaneously within the meaning of the invention are exposed to the same measurement voltage, the further advantage is achieved that the measured or diagnostic results then obtained can be compared more effectively, since all measurement objects receive the absolutely identical measurement voltage in the course of a measurement process. Such comparability of the acquired data is not possible with separate and consecutive measurements or diagnoses of individual measurement objects, as is the case in the prior art. Furthermore, the present invention needs only one (high) voltage source for the simultaneous diagnosis of several measurement objects and also, in the case of an external (high) voltage source, only one supply line to the inventive device has to be provided.

Within the scope of the present invention, especially for purposes of cable testing, the high-voltage source is preferably designed to generate a sinusoidal AC voltage with rms values in the range of 1 kV to 100 kV at a frequency of approximately 0.1 Hz.

In a first particularly preferred configuration of the present invention, it is provided that the device comprises exactly three separate connection elements, each for connecting one measurement object to the measurement voltage, and exactly three current-detection units, so that simultaneous diagnosis of all three cores of a three-core cable is possible.

Heretofore, for the purpose of (nondestructive) diagnosis of 3-phase (high) voltage cables, the individual cores of the cable have always been measured separately. With the measurement device described in the foregoing, it is possible to carry out a complete cable test in very much shorter time; as a bonus result there is obtained a measurement record that, on the basis of an identical measurement voltage for all cores of the cable, permits an independent calculation of the loss factor for all three conductors of the three-core cable. In this regard it must be pointed out that it is entirely possible for the loss factor or the quality of the individual cores of a 3-core cable to be different, and this can also be recognized more effectively with an inventive device.

In principle, the connection elements of an inventive device may be constructed in different manners and styles, for example, by clamped, inserted or screwed contacts. Within the scope of the present invention, it is particularly preferred to provide that the housing has an electrically conductive housing part, which forms the connecting elements and to which the measurement voltage is applied for direct or indirect connection of the measurement objects, this conductive housing part being subdivided into several segments insulated from one another, each for connection of one measurement object. In each segment of such a conductive housing part, therefore, there is formed one connection element, to which precisely one measurement object can be connected for the inventive diagnostic purposes.

The housing is preferably provided with a cylindrical housing portion, which for the purpose of forming the conductive housing part is equipped with a conductive cap, which in turn is subdivided into individual segments insulated from one another. The number of segments then corresponds to the maximum number of measurement objects that can be tested simultaneously, for which purpose a separate current-detection unit for each segment of the conductive housing part is to be provided inside the housing. The measurement voltage applied equally to all segments can be measured with a single voltage-detection unit, for example in the form of a voltage divider.

To increase the measurement accuracy, it is additionally possible to allocate a leakage-current detector to each individual (high) voltage output, in order to measure any leakage currents of the device. During evaluation of the measurement results, it is then possible to allow for these leakage currents for the several measurement objects, in other words by computationally removing them from the measurement results for the respective current flow to the extent they falsify such results. This is particularly expedient, especially in the high-voltage range at (rms) voltages higher than 1 kV or higher than 20 kV, since herewith—besides the measurement accuracy as such—the comparability of the evaluation of the measurement results for the various simultaneously tested measurement objects is further enhanced.

Furthermore, according to yet another improvement of the invention, it is advantageously provided that an evaluation unit connected to the at least two current-detection units and to the one voltage-detection unit, and designed for simultaneous evaluation of all signals pertaining to the current and voltage measurement for several measurement objects, is disposed inside the housing of the device. In this context, simultaneous evaluation is to be understood in particular as simultaneous detection and storage of the signals output by the current-detection or voltage-detection units. In this way, especially in the case of testing of a multi-core cable, the loss factor for each simultaneously tested conductor of the cable in question can also be calculated already in the evaluation unit.

A further aspect of the present invention relates to the circumstance that the device preferably comprises a data-transmission unit, which cooperates with the evaluation unit and by means of which the measurement data present in the evaluation unit and obtained from a measurement process pertaining to several measurement objects can be transmitted in a single transmission process to an external data-processing unit. A conceivable external data-processing unit is in particular a mobile data-processing unit, for example a laptop, which then communicates via a suitable hard-wired or—preferably—wireless interface with the data-transmission unit of the inventive device. In this way, not only are the measurement objects to be tested measured simultaneously, but also the diagnosis process for all data pertaining to all measurement objects can be relayed in real time in only one transmission process to an external station for further processing, storage and/or display of the measured values or of the diagnostic result.

Wireless data transmission then proves to be advantageous in particular if—as is preferably provided in the present context—the entire electronics of the measurement circuit, including battery or accumulator for operation of the measurement circuit, evaluation unit and data-transmission unit are disposed on the high-voltage side, meaning that they are at high-voltage potential during a measurement process. In the prior art with hard-wired data transmission, signal measurement and evaluation usually take place on the low-voltage side, for which purposes separate coupling capacitors must be provided. Within the scope of the present invention, however, even optical data transmission may be advantageously implemented on the high-voltage side.

### BRIEF DESCRIPTION OF THE DRAWINGS

An exemplary embodiment of the invention will be explained in more detail hereinafter on the basis of the drawing, wherein

FIG. 1 shows a first schematic view of an inventive device for simultaneous diagnosis of three measurement objects,

FIG. 2 shows a schematic section through the housing of the inventive device from FIG. 1, and

FIG. 3 shows a perspective view of the device from FIG. 1.

### DETAILED DESCRIPTION

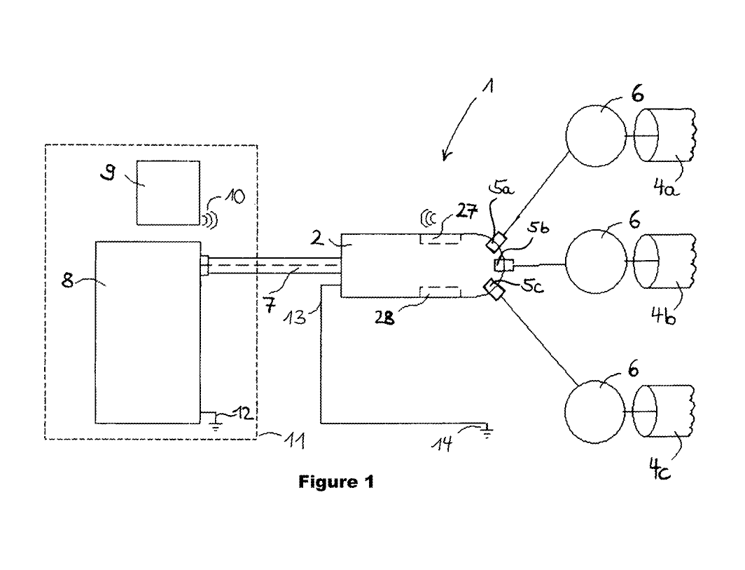

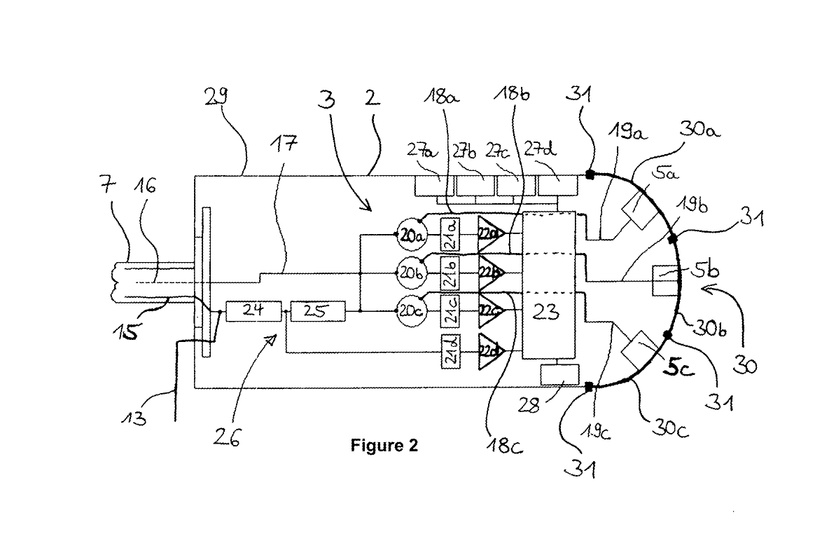

FIGS. 1 and 2 show a schematic view of an inventive device 1 for carrying out an electrical diagnosis of several measurement objects, which device is provided with a housing 2 and a measurement circuit 3 disposed inside housing 2. Illustrated device 1 is designed for simultaneous diagnosis of in total three measurement objects 4a, 4b, 4c. In the present context, the three measurement objects 4a, 4b, 4c are three cores (each provided with separate insulation) of a three-core high-voltage cable.

The device is provided with in total three connecting elements 5a, 5b, 5c, at which the three cited measurement objects 4a, 4b, 4c are connected via one spherical connection adapter 6 each. However, it is also possible to provide a direct connection of measurement objects 4a, 4b, 4c to connection elements 5a, 5b, 5c, for example by forming connecting elements 5a, 5b, 5c as suitable clamped, inserted or screwed connections.

Device 1 is connected via a coaxial cable 7 led into housing 2 to a programmable high-voltage source 8, which—together with a display/control unit 9 and a data-processing device 10 that may be provided (and which may be designed, for example, for wireless control of the high-voltage source by an external data-processing unit)—is disposed inside a shielded housing 11 of the high-voltage generator. This high-voltage source 8 is grounded in the usual way via a protective ground connection 12.

Protective conductor 15, connected to measurement circuit 3, of coaxial cable 7 also defines the ground potential for measurement circuit 3 of device 1, for which purpose device 1 is once again connected separately via cable 13 to a suitable ground 14.

In contrast, the measurement voltage drawn from voltage source 8 is applied to inner conductor 16 of coaxial cable 7 and is then distributed via conductor structure 17, 18a-c, 19a-c to connection elements 5a-c. In between there are disposed current-detection units 20a, 20b, 20c respectively for detecting the current flowing through the respective measurement object 4a-c during a measurement process.

Each current-detection unit 18a, 18b, 18c is connected via a separate signal output and via an (optional) high-voltage protection element 21a, 21b, 21c as well as an (optional) signal filter or amplifier 22a, 22b, 22c to evaluation unit 23 of device 1. Conductor portions 18a-c are each routed around evaluation unit 23, as indicated by dashed lines.

Furthermore, measurement circuit 3 comprises a voltage divider, which is composed of resistors 24, 25, which forms a voltage-detection unit 26 for detection of the measurement voltage applied equally at each instant to all three connection elements 5a, 5b, 5c, and whose output signal is also connected via an (optional) high-voltage protection element 21d and an (optional) signal filter or amplifier 22d to evaluation unit 23.

In evaluation unit 23, the signals arriving during a measurement or diagnosis process from current-detection units 20a-c and from voltage-detection unit 26 are simultaneously evaluated, meaning in particular that they are stored and conditioned for future or if necessary immediately following data transmission to an external data-processing unit, not illustrated. In particular, analog-to-digital conversion of the signals arriving at the evaluation unit is conceivable for this purpose, although it is also possible, for example, for current-detection units 20a-c to be provided already with an analog-to-digital converter. For transmission of the data present in the evaluation unit, device 1 is equipped with a suitable data-transmission unit 27a-c, which is connected to the evaluation unit and by means of which the entire data of a measurement process pertaining to measurement objects 4a-c can be transmitted, preferably wirelessly. As an example, this may be a Bluetooth interface 27a, an infrared interface 27b and/or a hard-wired (optical or electronic) data interface 27c. Furthermore, there is provided a visual display unit 27d, by means of which a measurement or diagnosis result, such as a loss factor calculated by evaluation unit 23 for the core in question of a multi-core cable, can be displayed, preferably for all connectable or connected measurement objects 4a-c. The electrical power necessary for operation of measurement circuit 3 is preferably drawn from a rechargeable accumulator 28.

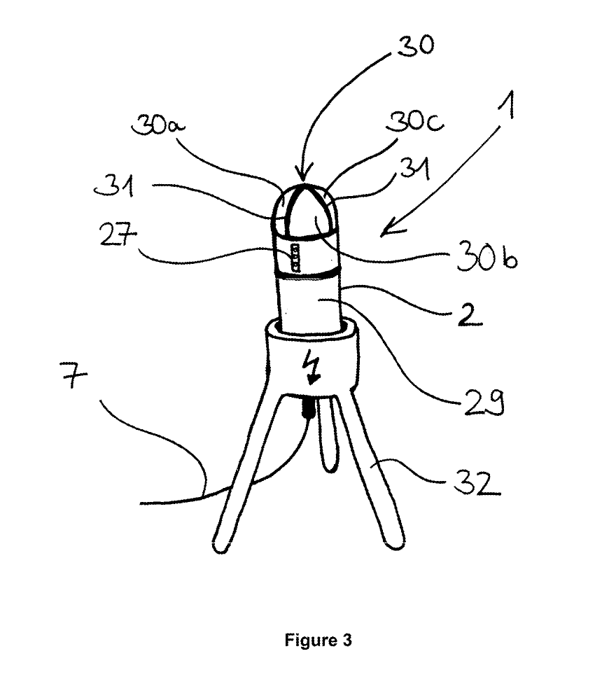

Housing 2 of device 1 is composed of a cylindrical base shell 29 made preferably of plastic or of another non-conductive material and is bounded at one end—illustrated at the right in FIG. 2 and at the top in FIG. 3—by a conductive end cap 30 of a suitable metal. This conductive housing part 30 is subdivided by means of suitable insulators 31 into in total three segments 30a, 30b, 30c, which are insulated from the rest of the housing and from one another, and in each of which there is formed one connection element 5a, 5b, 5c for the measurement objects 4a, 4b, 4c to be connected.

Finally, FIG. 3 also shows inventive device 1 in perspective view. Device 1 is connected via a coaxial cable 7 to a programmable high-voltage generator, not illustrated in FIG. 3. Device 1, together with a lower end of housing 2, is received firmly in a stand 32 and at its upper end is provided with a conductive housing part 30 in the form of the metal end cap subdivided into three segments 30a, 30b, 30c. As is readily apparent in FIG. 3, individual segments 30a-c are insulated from one another and from the rest of housing 29 by suitable insulators 31, and are used for connection of the in total three measurement objects. Furthermore, data-transmission and display device 27 can be seen on the outside of the housing.

We claim:

1. A device (1) for diagnosing measurement objects (4a, 4b, 4c) using a measurement voltage, comprising:
a housing (2), in which there is disposed at least one electrical measurement circuit (3) for carrying out the diagnosis,
the device (1) being designed for simultaneous diagnosis of several measurement objects (4a, 4b, 4c) with the same measurement voltage and further comprises at least two separate connection elements (5a, 5b, 5c), each for connecting one measurement object (4a, 4b, 4c) to the measurement voltage, wherein the at least one electrical measurement circuit (3) comprises at least two current-detection units (20a, 20b, 20c) and one voltage-detection unit (26), by means of which the current flowing through each measurement object (4a, 4b, 4c) as well as the measurement voltage applied equally to all measurement objects (4a, 4b, 4c) can be measured simultaneously.

2. A device according to claim 1, wherein the device (1) comprises exactly three separate connection elements (5a, 5b, 5c), each for connecting one measurement object (4a, 4b, 4c) to the measurement voltage, and exactly three current-detection units (20a, 20b, 20c), so that simultaneous diagnosis of all three cores of a three-core cable is possible.

3. A device according to claim 1, wherein the housing (2) is provided with an electrically conductive housing part (30), which forms the connection elements (5a, 5b, 5c) and at which the measurement voltage for connection of the measurement objects (4a, 4b, 4c) is applied, the electrically conductive housing part (30) being subdivided into several segments (30a, 30b, 30c), insulated from one another, for connection of one measurement object (4a, 4b, 4c) each.

4. A device according to claim 1, wherein an evaluation unit (23) connected to the at least two current-detection units (20a, 20b, 20c) and to the one voltage-detection unit (26), and designed for simultaneous evaluation of all signals pertaining to the current and voltage measurement for several measurement objects (4a, 4b, 4c), is disposed inside the housing (2).

5. A device according to claim 1, further comprising a data-transmission unit (27a, 27b, 27c), which cooperates with the evaluation unit (23) and by means of which measurement data present in the evaluation unit (23) and obtained from a measurement process pertaining to several measurement objects (4a, 4b, 4c) can be transmitted in a single transmission process to an external data-processing unit.

6. A device according to claim 5, wherein an entire electronics of the device (1) are disposed on the high-voltage side, and in that the data-processing unit (27a, 27b, 27c) provides an optical and/or wireless data interface.
